(19) United States
(12) Patent Application Publication
(10) Pub. No.: US 2010/0007364 A1
(43) Pub. Date: Jan. 14, 2010

(54) Hot Testing of Semiconductor Devices

(75) Inventor: Eddy Van Esch, Tessenderlo (BE)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: XPEQT NV, Tessenderlo (BE)

(21) Appl. No.: 12/440,911

(22) PCT Filed: Sep. 11, 2007
(86) PCT No.: PCT/IB07/02607

§ 371 Date: Sep. 24, 2009

(30) Foreign Application Priority Data
Sep. 11, 2006 (GB) 0617835.4

(51) Int. Cl. G01R 31/02

(52) U.S. Cl. 324/760

(57) ABSTRACT

A testing apparatus for testing of integrated circuit devices at elevated temperatures comprises hot belt 111 is operable to transport integrated circuits from a main production line into a hot chamber 121 and thence onto a test area 122 within the hot chamber 121 and a cold belt 112 operable to receive integrated circuits from the test area 122 and transport them back to the main production line. Both the hot and cold belts 111, 112 are indexed stepwise, the indexing distance being equal to the separation of the pockets provided for receiving integrated circuits. In the test area 122 are four vacuum chucks 131a-131d each operable to pick an integrated circuit from adjacent pockets on the hot belt 111 and place it on corresponding test heads 133a-133d (via a corresponding repositioning means 132a-132d) for diagnostic testing at an elevated temperature. After testing, the vacuum chucks 131a-131d are operable to pick the integrated circuits from the corresponding test heads 133 a-133d and place them in adjacent pockets on the cold belt 112.

The present invention relates to hot testing of semiconductor devices, and in particular to an apparatus for the same.

Integrated circuits (ICs) are typically designed to be fully operational within a specified range of temperatures. In some applications this range is wide enough to approach the limits of the various technologies involved. The need to operate an IC at temperatures as high as 150° C. or more, for example, often leads to additional complication and expense at the testing stage.

Traditionally, apparatus to implement such testing is custom built for the particular purpose. This means that it can be difficult to add such functionality to an existing production line. Additionally, it can cause difficulties if such testing apparatus breaks down.

It is therefore an object of the present invention to provide a test apparatus operable for testing integrated circuits at elevated temperatures that alleviates or overcomes the above problems.

According to a first aspect of the present invention there is provided a testing apparatus for testing of integrated circuits at elevated temperatures comprising: a hot belt adapted to receive one or more integrated circuits and operable to transport said integrated circuits to a test area, the integrated circuits on said hot belt and within said test area being heated to and maintained at a desired elevated temperature; one or more test heads located in said test area and operable to receive and test one or more integrated circuits; a cold belt adapted to receive one or more integrated circuits and operable to transport said integrated circuits away from said test area; and pick and place means operable to move one or more integrated circuits from said hot belt to said test head or heads and operable to move said one or more integrated circuits from said test head or heads to said cold belt.

By use of the above apparatus, devices received by the hot belt can be transported to a test area, tested at an elevated temperature and transported away from the test area to a desired location using said cold belt.

Preferably, the hot belt is adapted to receive integrated circuits from a suitable hot belt pick and place means. Similarly, the cold belt is preferably adapted to transport integrated circuits to a suitable cold belt pick and place means. In some embodiments, the hot and cold belts may be served by a combined hot and cold belt pick and place means. This allows the apparatus to be provided as a dedicated module that can be rapidly introduced into or taken out of an existing production line. In such circumstances the combined hot and cold belt pick and place means may be a rotatable turret having a plurality of vacuum chucks arranged around its periphery. The vacuum chucks may be operable to place integrated circuits onto the hot belt one by one and to take integrated circuits off the cold belt one by one. Typically, the integrated circuits may be taken from and returned to a main belt by the turret.

The hot belt and the cold belt may be adapted to receive integrated circuits by being provided with a plurality of pockets on their upper surface. Each pocket is preferably adapted to retain a single integrated circuit. The pockets are preferably arranged in single file along each belt.

Both the hot and cold belts are preferably indexed step wise rather than being continuously driven. Each indexing step preferably corresponds to the separation between adjacent pockets.

Preferably the test area is provided within a hot chamber. Preferably, the hot chamber is maintained at an elevated temperature by the provision of suitable heating means. The hot chamber may be maintained at any desired temperature. The temperature of the hot chamber may be adjustable. Preferably, the temperature may be adjusted depending on the particular device under test. For typical applications, the hot chamber may be maintained at a temperature in the range 100-150° C.

Preferably, at least a portion of the hot belt lies within the hot chamber. Accordingly, the integrated circuits on the hot belt are heated to an elevated temperature before being tested. Preferably, the cold belt lies outside the hot chamber. The cold belt is thus at the same ambient temperature as the surrounding environment and the integrated circuits on the cold belt thus cool back to the ambient temperature. In the event that the integrated circuits do not cool sufficiently quickly, cooling means may be provided to lower the temperature of the integrated circuits on the cold belt to the ambient temperature before they are returned to the turret.

The pick and place means may comprise one or more vacuum chucks.

A repositioning head may be provided adjacent to the or each test head. The repositioning head may be operable to receive the integrated circuit for test from said pick and place means prior to the test head. The repositioning head may be operable to correct the position and orientation of a received integrated circuit such that when it is repicked by said pick and place means it is in the correct orientation to be received by the test head.

The repositioning means and the test head may have replaceable modules. The replaceable modules allow the repositioning means and the test heads to be adapted to test different integrated circuits.

In one preferred embodiment the pick and place means comprises four vacuum chucks and there are provided four repositioning means and four test heads. Preferably, each vacuum chuck is adapted to lift integrated circuits between the hot belt and the cold belt via an associated repositioning means and an associated test head. Additionally and preferably the vacuum chucks are adjacent to one another and operable to pick and place integrated circuits from four adjacent pockets on the hot belt. Preferably, the four vacuum chucks are operable in a four step cycle comprising the following steps:
1. lift integrated circuits from four adjacent pockets on the hot belt and place said integrated circuits on said repositioning means;
2. lift said integrated circuits from said repositioning means and then place said integrated circuits on said test heads;
3. lift said integrated circuits from said test heads and then place said integrated circuits in four adjacent pockets on the cold belt; and
4. return to a starting position over said hot belt.

Preferably, each of said hot and cold belts indexes one step forward simultaneously with the each of the above steps. In this manner, four integrated circuits are tested during a four phase cycle and additionally, four new integrated circuits have moved into position on the hot belt by the end of the cycle and four free pockets are provided on said cold belt by step 3 of the cycle. The test apparatus can therefore run continuously.

Whilst the above description has referred to the testing of integrated circuits, it should be understood to also encompass the testing of completed integrated circuit devices.

In order that the invention can be more clearly understood it is now described further below with reference to the accompanying drawings:

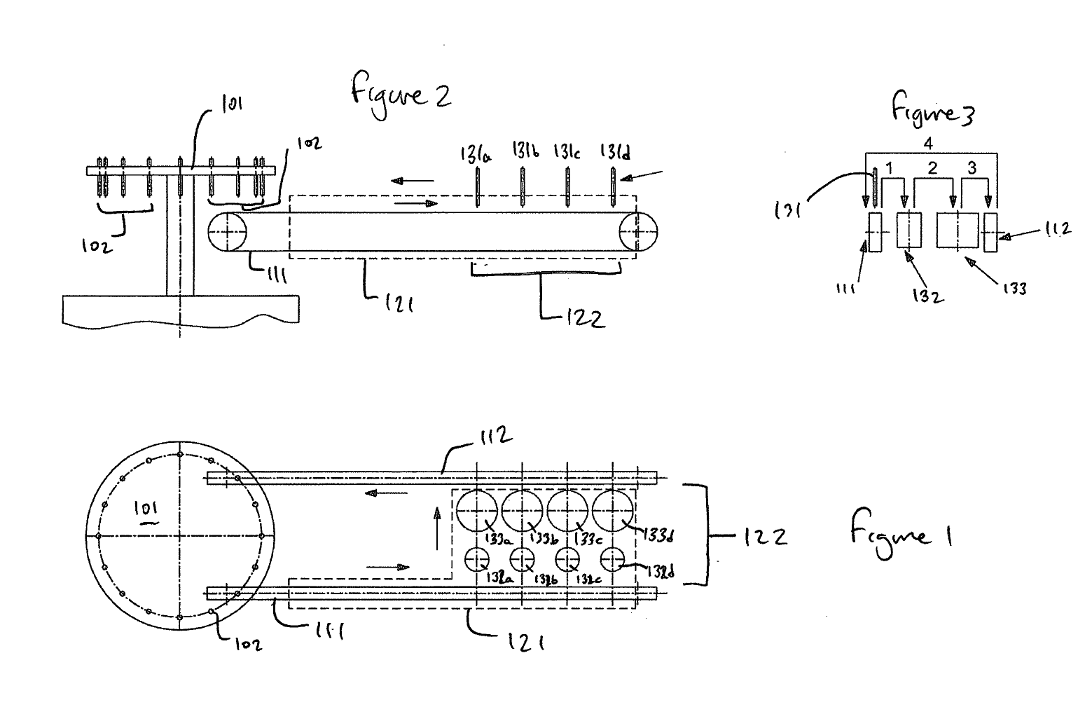

FIG. 1 shows a schematic top view of the test apparatus of the present invention;

FIG. 2 shows a schematic side view of the test apparatus of the present invention; and

FIG. 3 shows a schematic front view of the test apparatus of the present invention.

Referring now to FIGS. 1 to 3, a testing apparatus for testing of integrated circuit devices at elevated temperatures comprises a rotatable turret 101 provided with a plurality of vacuum chucks 102. The vacuum chucks 102 are operable to pick integrated circuits (not shown) for testing from a main production line (not shown) and then to place the integrated circuits in pockets (not shown) provided on a ‘hot’ conveyor belt 111, once the turret has rotated sufficiently. The vacuum chucks 102 are further operable to pick integrated circuits (not shown) that have been tested from pockets (not shown) provided on a ‘cold’ conveyor belt 112 and return the tested integrated circuits to the main conveyor belt, once the turret 101 has rotated sufficiently. Typically, the turret 101 is adapted to rotate in an indexed manner.

The hot belt 111 is operable to transport integrated circuits from the turret 101 into a hot chamber 121 and thence onto a test area 122 within the hot chamber 121. The cold belt 112 is operable to receive integrated circuits from the test area 122 and transport them back to the turret 101. Both the hot and cold belts 111, 112 are indexed stepwise, the indexing distance being equal to the separation of the pockets provided for receiving integrated circuits.

The hot chamber 121 is maintained at a desired elevated temperature, typically in the region of 150° C. This allows the integrated circuits carried by the hot belt 111 to be elevated to the same temperature as the hot chamber 121. In alternative embodiments however the particular temperature of the hot chamber 121 is selected to be appropriate to the particular integrated circuits being tested. The temperature of the hot chamber 121 is maintained by suitable heating means (not shown).

The cold belt 112 remains at the ambient temperature of the environment. Integrated circuits placed on the cold belt 112 from the hot chamber 121 thus cool back to the ambient temperature.

In the present embodiment there is provided in the test area 122 four vacuum chucks 131a-131d each of which is operable to pick an integrated circuit from adjacent pockets on the hot belt 111. Each picked integrated circuit is then placed on a corresponding repositioning means 132a-132d and released (step 1 in FIG. 3). The repositioning means are operable to manipulate the position and orientation of the integrated circuits into a particular desired orientation.

Subsequently the vacuum chucks 131a-131d are operable to pick the integrated circuits from the corresponding repositioning means and place the integrated circuits on corresponding test heads 133a-133d (step 2 in FIG. 3). The test heads are operable to run one or more diagnostic tests on the integrated circuits to verify their correct performance at an elevated temperature.

After testing is complete, the vacuum chucks 131a-131d are operable to pick the integrated circuits from the corresponding test heads 133a-133d and place them in adjacent pockets on the cold belt 112, which is outside the hot chamber 121 (step 3 in FIG. 3). The integrated circuits can thus cool on their way back to the turret 101.

After the integrated circuits are placed on the cold belt, 112, the vacuum chucks 131a-131d are moved back into position over the hot belt 111 (step 4 in FIG. 3). Whilst each of the above steps takes place, both the hot and cold belts are indexed forward one step. Accordingly, by the time the cycle is ready to repeat, four new integrated circuits are positioned in pockets adjacent to the vacuum chucks 131a-131d. Similarly, by the time step 3 is reached, there are four empty pockets provided on the cold belt adjacent to the vacuum chucks 131a-131d.

This allows one new integrated circuit to be placed on the hot belt 111 and one new integrated circuit to be removed from the cold belt 112 after each indexed step and thus a continuous stream of integrated circuits can be tested. In order to maintain order, the indexing of the turret 101 and the main conveyor belt are preferably matched to the indexing of the hot and cold belts 111, 112.

It is of course to be understood that the invention is not to be restricted to the details of the above embodiments which have been described by way of example only.

1. A testing apparatus for testing of integrated circuits at elevated temperatures comprising: a hot belt adapted to receive one or more integrated circuits and operable to transport said integrated circuits to a test area, the integrated circuits on said hot belt and within said test area being heated to and maintained at a desired elevated temperature; one or more test heads located in said test area and operable to receive and test one or more integrated circuits; a cold belt adapted to receive one or more integrated circuits and operable to transport said integrated circuits away from said test area; and pick and place means operable to move one or more integrated circuits from said hot belt to said test head or heads and operable to move said one or more integrated circuits from said test head or heads to said cold belt, wherein the hot and cold belts are served by a combined hot and cold belt pick and place means, the combined hot and cold belt pick and place means comprising a rotatable turret having a plurality of vacuum chucks arranged around its periphery.

2. A testing apparatus as claimed in claim 1 wherein the hot belt is adapted to receive integrated circuits from a hot belt pick and place means and the cold belt is adapted to transport integrated circuits to a cold belt pick and place means.

3. (canceled)

4. (canceled)

5. (canceled)

6. A testing apparatus as claimed in claim 1 wherein the vacuum chucks are operable to place integrated circuits onto the hot belt one by one and to take integrated circuits off the cold belt one by one.

7. A testing apparatus as claimed in claim 1 wherein the integrated circuits are taken from and returned to a main belt by the turret.

8. A testing apparatus as claimed in claim 1 wherein the hot belt and the cold belt are adapted to receive integrated circuits by being provided with a plurality of pockets on their upper surface, each pocket being adapted to retain a single integrated circuit.

9. (canceled)

10. (canceled)

11. A testing apparatus as claimed in claim 5 wherein the hot and cold belts are indexed step wise, each indexing step corresponding to the separation between adjacent pockets.

12. (canceled)

13. A testing apparatus as claimed in claim 1 wherein the test area is provided within a hot chamber, the hot chamber being maintained at an elevated temperature by the provision of suitable heating means.

14. (canceled)

15. A testing apparatus as claimed in claim 7 wherein the temperature of the hot chamber is adjustable.

16. (canceled)

17. A testing apparatus as claimed in claim 7 wherein at least a portion of the hot belt lies within the hot chamber and wherein the cold belt lies outside the hot chamber.

18. A testing apparatus as claimed in claim 7 wherein the integrated circuits on the hot belt are heated to an elevated temperature before being tested and wherein cooling means are provided to lower the temperature of the integrated circuits on the cold belt to the ambient temperature.

19. (canceled)

20. (canceled)

21. A testing apparatus as claimed in claim 1 wherein the pick and place means comprises one or more vacuum chucks.

22. A testing apparatus as claimed in claim 1 wherein a repositioning head is provided adjacent to the or each test head, the repositioning head being operable to receive the integrated circuit for test from said pick and place means prior to the test head so as to correct the position and orientation of a received integrated circuit such that when it is repicked by said pick and place means it is in the correct orientation to be received by the test head.

23. (canceled)

24. (canceled)

25. A testing apparatus as claimed in claim 12 wherein the repositioning means and the test head have replaceable modules.

26. (canceled)

27. A testing apparatus as claimed in claim 12 wherein the pick and place means comprises four vacuum chucks and there are provided four repositioning means and four test heads, each vacuum chuck being adapted to lift integrated circuits between the hot belt and the cold belt via an associated repositioning means and an associated test head and wherein the vacuum chucks are adjacent to one another and operable to pick and place integrated circuits from four adjacent pockets on the hot belt.

28. (canceled)

29. (canceled)

30. A testing apparatus as claimed in claim 14 wherein the four vacuum chucks are operable in a four step cycle comprising the following steps: 1. lift integrated circuits from four adjacent pockets on the hot belt and place said integrated circuits on said repositioning means; 2. lift said integrated circuits from said repositioning means and then place said integrated circuits on said test heads; 3. lift said integrated circuits from said test heads and then place said integrated circuits in four adjacent pockets on the cold belt; and 4. return to a starting position over said hot belt wherein each of said hot and cold belts indexes one step forward simultaneously with the each of the steps.

31. (canceled)
